(19) United States
(12) Patent Application Publication
(10) Pub. No.: US 2026/0101687 A1
(43) Pub. Date: Apr. 9, 2026

(54) SEMICONDUCTOR CHIP AND METHOD OF MANUFACTURING THE SAME

(71) Applicant: SAMSUNG ELECTRONICS CO., LTD., Suwon-si (KR)

(72) Inventors: Sangjine PARK, Suwon-si (KR); Ji Hwan PARK, Suwon-si (KR)

(73) Assignee: SAMSUNG ELECTRONICS CO., LTD., Suwon-si (KR)

(21) Appl. No.: 19/191,949

(22) Filed: Apr. 28, 2025

(30) Foreign Application Priority Data
Oct. 7, 2024 (KR) 10-2024-0136070

(51) Int. Cl. H01L 21/268; B23K 26/53; B23K 101/40; C30B 29/06; H01L 21/02; H01L 23/00

(52) U.S. Cl. CPC H10P 34/42; B23K 26/53; C30B 29/06; H10P 14/2905; H10W 42/121; B23K 2101/40

(57) ABSTRACT

A semiconductor chip includes a semiconductor substrate, a semiconductor device layer, and an insulation layer. The semiconductor substrate extends from first and second surfaces that are spaced apart and includes first and second regions with distinct single crystal structures. The semiconductor device layer is positioned on one surface of the semiconductor substrate, and the insulation layer envelops at least the upper and side surfaces of the semiconductor device layer. A plurality of penetration holes may be formed in the insulation layer. A laser may irradiate the semiconductor substrate to form the crystal structures. The laser may irradiate through the plurality of penetration holes.

### CROSS-REFERENCE TO RELATED APPLICATION

This application claims priority to and the benefit of Korean Patent Application No. 10-2024-0136070 filed in the Korean Intellectual Property Office on Oct. 7, 2024, the entire contents of which are incorporated herein by reference.

### BACKGROUND

### 1. Field

The present disclosure relates to a semiconductor chip and a manufacturing method thereof.

### 2. Description of the Related Art

The technology of stacking a plurality of chips in a semiconductor package has evolved in response to the ongoing need to improve the performance and miniaturize semiconductor integrated circuits (ICs). In particular, research is actively being conducted on the technology that can simultaneously realize high performance, multi-function, and miniaturization by stacking the plurality of chips in a single package.

However, when polishing the back of the wafer to reduce the thickness and the volume, a stress is applied to the wafer during the polishing process. Thin wafers may bend due to the applied stress, which may cause warping of the semiconductor chip. Warping may cause poor contact between semiconductor chips in a stack. Methods and systems to reduce such warping and increase the reliability of semiconductor devices are being developed.

### SUMMARY

Embodiments described herein provide a semiconductor chip with reduced or minimal chip warpage of a chip unit.

A semiconductor chip according to some embodiments may include a semiconductor substrate. The semiconductor substrate may extend from a first surface to a second surface; wherein the first surface extends along a first axis and a second axis orthogonal to the first axis; wherein the second surface extends along the first axis and the second axis; and wherein the first surface faces the second surface and is spaced apart from the second surface along a third axis orthogonal to the first axis and the second axis. A first region of semiconductor substrate may include a first single crystal structure, and a second region of the semiconductor substrate may comprise a second crystal structure different from the first single crystal structure. The semiconductor chip may include a semiconductor device layer and an insulation layer disposed on the first surface of a semiconductor substrate. The semiconductor device layer may include an upper surface that extends along the first axis and the second axis and a side surface that extends from an edge of the upper surface to the first surface of the semiconductor substrate along the third axis. The side surface and the upper surface may be covered by the insulation layer.

A semiconductor chip according to some embodiments may include a semiconductor substrate extending from a first surface to a second surface, wherein the first surface extends along a first axis and a second axis orthogonal to the first axis; wherein the second surface extends along the first axis and the second axis; and wherein the first surface faces the second surface and is spaced apart from the second surface along a third axis orthogonal to the first axis and the second axis. The semiconductor chip may include a semiconductor device layer extending from a first upper surface to a first lower surface that is disposed on the first surface of the semiconductor substrate; wherein the first upper surface and the first lower surface both extend along the first axis and the second axis, wherein the first upper surface faces the first lower surface and is spaced apart from the first lower surface along the third axis. The semiconductor device layer may include a side surface that extends from an edge of the first upper surface to an edge of first lower surface along the third axis. The semiconductor chip may include an insulation layer extending from a second upper surface to a second lower surface that is disposed on the first surface of the semiconductor substrate; wherein, the second upper surface and the second lower surface both extend along the first axis and the second axis, wherein the second upper surface faces the second lower surface and is spaced apart from the second lower surface along the third axis. The insulation layer may cover the side surface and the first upper surface. The semiconductor chip may include a plurality of penetration holes extending through the insulation layer from the second upper surface along the third axis.

A method of manufacturing a semiconductor chip according to some embodiments may include providing a providing a semiconductor substrate that extends from a first surface to a second surface; wherein the first surface extends along a first axis and a second axis orthogonal to the first axis; wherein the second surface extends along the first axis and the second axis; and wherein the first surface faces the second surface and is spaced apart from the second surface along a third axis orthogonal to the first axis and the second axis. The method of manufacturing a semiconductor chip may include forming a semiconductor device layer that extends from a first upper surface to a first lower surface disposed on the first surface of the semiconductor substrate; wherein the first upper surface and the first lower surface both extend along the first axis and the second axis, wherein the first upper surface faces the first lower surface and is spaced apart from the first lower surface along the third axis. The semiconductor device layer may include a side surface that extends from an edge of the first upper surface to an edge of first lower surface along the third axis. The method of manufacturing a semiconductor chip may include forming an insulation layer that extends from a second upper surface to a second lower surface disposed on the first surface of the semiconductor substrate; wherein the second upper surface and the second lower surface both extend along the first axis and the second axis, wherein the second upper surface faces the second lower surface and is spaced apart from the second lower surface along the third axis. The method of manufacturing a semiconductor chip may include irradiating the semiconductor substrate with a laser, wherein the irradiating forms, in the semiconductor substrate between the first surface and the second surface, a first region having a first single crystal structure and a second region having a second crystal structure different from the first single crystal structure.

According to embodiments, a chip warpage may be controlled by controlling a compressive stress or tensile force within the semiconductor substrate.

### BRIEF DESCRIPTION OF THE DRAWINGS

FIG. 1 illustrates a top plan view of a semiconductor package, consistent with embodiments of the present disclosure.

FIG. 2 illustrates a cross-sectional view of a semiconductor package, consistent with embodiments of the present disclosure.

FIG. 3 to FIG. 8 illustrates cross-sectional views of a semiconductor chip, consistent with embodiments of the present disclosure.

FIG. 9 to FIG. 12 illustrate a manufacturing method of a semiconductor chip, consistent with embodiments of the present disclosure.

FIG. 13 to FIG. 16 illustrate a manufacturing method of a semiconductor chip, consistent with embodiments of the present disclosure.

FIG. 17 and FIG. 18 illustrate a manufacturing method of a semiconductor chip, consistent with embodiments of the present disclosure.

FIG. 19 to FIG. 26 illustrate a manufacturing method of a semiconductor chip, consistent with embodiments of the present disclosure.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Descriptions of parts not related to the present disclosure are omitted, and like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means viewing the object portion from the top, and the phrase “on a cross-section” means viewing a cross-section of which the object portion is vertically cut from the side.

Additionally, throughout the specification, two directions parallel to and intersecting the first surface of the semiconductor substrate are defined as a first direction D1 and a second direction D2, respectively, and a direction perpendicular to the first surface of the semiconductor substrate is described as a third direction D3. For example, the first direction D1 and the second direction D2 may be orthogonal to each other.

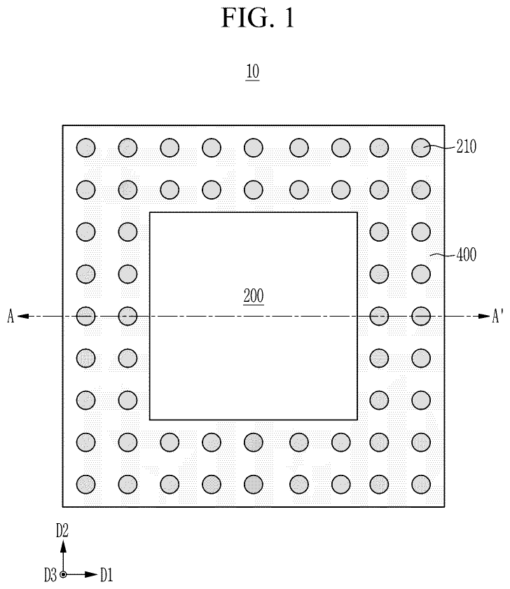

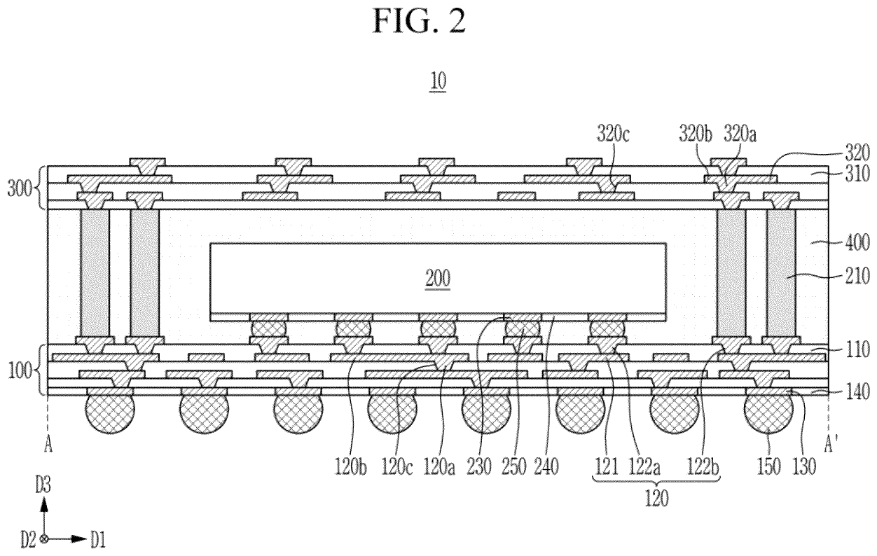

FIG. 1 illustrates a top plan view of a semiconductor package 10, and FIG. 2 illustrates a cross-sectional view of a semiconductor package 10.

For clarity and simplicity of illustration, FIG. 1 illustrates a semiconductor chip 200, connection structures 210, and a molding layer 400 of the semiconductor package 10.

Referring to FIG. 1 and FIG. 2, the semiconductor package 10 may comprise a first redistribution substrate 100, the semiconductor chip 200, the connection structures 210, a second redistribution substrate 300, and the molding layer 400.

According to some embodiments, the first redistribution substrate 100 may comprise a plurality of first insulation layers 110 that are mutually laminated. For example, FIG. 2 illustrates the lamination of three first insulation layers 110, but the present disclosure is not limited thereto. The number of the first insulation layers 110 laminated within the first redistribution substrate 100 may be provided in various ways as required.

According to some embodiments, the first insulation layers 110 may comprise organic materials, such as, for example, photo-imageable dielectric (PID) materials. The photo-imageable dielectric material may be a polymer. The photo-imageable dielectric material may comprise, for example, at least one of a photosensitivity polyimide, a polybenzooxazole, a phenol-based polymer, and a benzocyclobutene-based polymer. For example, FIG. 2 shows the boundary between the first insulation layers 110, but the present disclosure is not limited thereto. According to some embodiments, the interface between the adjacent first insulation layers 110 may be indistinguishable.

According to some embodiments, the first redistribution patterns 120 may be provided within the first insulation layers 110. The first redistribution patterns 120 may have a first via portion 120a and a first wiring portion 120b connected integrally to each other. The first wiring portion 120b may be a pattern for a horizontal connection within the first redistribution substrate 100. The first via portion 120a may be a portion that vertically connects the first redistribution patterns 120 within the first insulation layers 110. The first wiring portion 120b may be provided on the first via portion 120a. The first wiring portion 120b may be connected to the first via portion 120a without an interface. The width of the first wiring portion 120b may be larger than the width of the first via portion 120a. In other words, each of the first redistribution patterns 120 may have the cross-section of a T shape. The first wiring portion 120b of the first redistribution patterns 120 may be positioned on the upper surface of the first insulation layers 110. The first via portion 120b of the first redistribution patterns 120 may pass through the first insulation layers 110 and be connected to the first wiring portion 120b of another first redistribution patterns 120 arranged underneath. The first redistribution patterns 120 may comprise a conductive material. For example, the first redistribution pattern 120 may contain copper (Cu).

According to some embodiments, seed patterns (not shown) may be placed on the undersides of the first redistribution patterns 120. For example, the seed patterns may cover the lower surface of the first via portion 120a, a side wall 120c, and the lower surface of the first wiring portion 120b of the corresponding first redistribution patterns 120, respectively. The seed patterns may a different material than the first redistribution patterns 120. For example, the seed patterns may comprise copper (Cu), titanium (Ti) or alloys thereof. The first redistribution patterns 120 may further comprise a barrier layer (not shown) to prevent diffusion of the material included in the first redistribution patterns 120. The barrier layer may comprise titanium nitride (TiN) or tantalum nitride (TaN).

According to some embodiments, the first redistribution patterns 120 may comprise first wiring patterns 121 and first redistribution pads 122a and 122b. The first redistribution pads 122a and 122b may be part of the first redistribution pattern 120 positioned on top of the first redistribution substrate 100. For example, the first redistribution pads 122a and 122b may be the first redistribution patterns 120 exposed on the upper surface of the first redistribution substrate 100. The first redistribution pads 122a, and 122b may be connected to the first wiring patterns 121 arranged thereunder. The first redistribution patterns 120 may be a wiring pattern electrically connected to the semiconductor chip 200, for example as described below, to redistribute signals to or from the semiconductor chip 200.

According to some embodiments, the substrate pads 130 may be provided beneath the lowermost first insulation layer 110 among the first insulation layers 110. The substrate pads 130 may be spaced apart from each other in the first direction D1. The substrate pads 130 may be connected to the first redistribution patterns 120. For example, the first via portion 120a of the lowermost first redistribution pattern 120 among the first redistribution patterns 120 may penetrate the first insulation layer 110 and be connected to the substrate pads 130. The substrate pads 130 may be electrically connected to the first redistribution pads 122a and 122b via the first wiring patterns 121. The substrate pads 130 may comprise a conductive material. For example, the substrate pads 130 may comprise copper (Cu).

According to some embodiments, the substrate protection layer 140 may be provided beneath the lowermost first insulation layer 110 in the third direction D3. The substrate protection layer 140 may surround the substrate pads 130 on the lowermost surface of the first insulation layer 110. The substrate protection layer 140 may expose the lower surface of the substrate pads 130. The substrate protection layer 140 may comprise a solder resist material.

According to some embodiments, the substrate connection terminals 150 may be arranged on the lower surface of the first redistribution substrate 100. The substrate connection terminals 150 may be provided on the lower surface of the substrate pads 130. The substrate connection terminals 150 may be spaced laterally from each other. The substrate connection terminals 150 may comprise a solder material. For example, the substrate connection terminals 150 may comprise tin (Sn), bismuth (Bi), lead (Pb), silver (Ag), or an alloy thereof.

According to some embodiments, the semiconductor chip 200 may be provided on the first redistribution substrate 100. The semiconductor chip 200 may be, for example, a logic chip or a buffer chip. The logic chip may comprise an application-specific integrated circuit (ASIC) chip or an application processor (AP) chip. Alternatively, the logic chip may comprise a central processing unit (CPU) or a graphics processing unit (GPU). The ASIC chip may comprise an application specific integrated circuit (ASIC). As another example, the semiconductor chip 200 may be a memory chip.

According to some embodiments, the semiconductor chip 200 may have chip pads 230 provided on the lower surface of the semiconductor chip 200. The chip pads 230 may be electrically connected to an IC formed within the semiconductor chip 200. The chip pads 230 may be exposed through the lower surface of semiconductor chip 200. The chip pads 230 may comprise a conductive material. The chip pads 230, for example, may comprise copper (Cu).

A chip passivation layer 240 may be provided on the lower surface of the semiconductor chip 200. The chip passivation layer 240 may surround the chip pads 230. The chip passivation layer 240 may not cover the chip pads 230, and the lower surface of the chip pads 230 may be exposed. The lower surface of the chip passivation layer 240 may be coplanar with the lower surface of the chip pads 230. The chip passivation layer 240 may comprise an insulating material such as silicon oxide (SiO), silicon nitride (SiN) or silicon nitride (SiCN).

According to some embodiments, semiconductor chip 200 may be mounted on the first redistribution substrate 100. For example, the semiconductor chip 200 may be mounted in a flip chip manner. More specifically, chip connection terminals 250 may be provided between the semiconductor chip 200 and the first redistribution substrate 100. The chip connection terminals 250 may be placed between the chip pads 230 of the semiconductor chip 200 and the first redistribution pads 122a of the first redistribution substrate 100. The chip connection terminals 250 may be connected to the chip pads 230 of the semiconductor chip 200 and the first redistribution pads 122a of the first redistribution substrate 100. Accordingly, the semiconductor chip 200 may be electrically connected to the first redistribution patterns 120 of the first redistribution substrate 100 via the chip connection terminals 250. The chip connection terminals 250 may comprise a conductive material. The chip connection terminals 250 may comprise, for example, copper (Cu).

According to some embodiments, a molding layer 400 may be disposed on the first redistribution substrate 100. The molding layer 400 may surround the semiconductor chip 200 on the first redistribution substrate 100. The molding layer of 400 may surround the chip connection terminals 250. The molding layer 400 may fill the space between the first redistribution substrate 100 and the semiconductor chip 200. Alternatively, the space between the first redistribution substrate 100 and the semiconductor chip 200 may be filled with an under-fill material. The side surface of the molding layer 400 may be vertically aligned with the side surface of the first redistribution substrate 100. The molding layer 400 may comprise an insulating polymer, such as an epoxy-based molding compound (EMC).

According to some embodiments, the connection structures 210 may be placed on the first redistribution substrate 100. The connection structures 210 may be placed on the first redistribution pads 122b of the first redistribution substrate 100. The connection structures 210 may vertically penetrate the molding layer 400 to connect the first redistribution substrate 100 and a second redistribution substrate 300 described below. The lower surface of connection structures 210 may be in contact with the upper surface of the first redistribution pads 122b. The connection structures 210 may be electrically connected to the semiconductor chip 200 through the first redistribution patterns 120 of the first redistribution substrate 100. The upper surface of the connection structures 210 may be coplanar with the upper surface of the molding layer 400. The connection structures 210 may be spaced apart from each other on the first redistribution substrate 100. The connection structures 210 may be spaced apart from the side surface of the semiconductor chip 200. The connection structures 210 may be arranged to surround the side surface of the semiconductor chip 200. The side surfaces of the connection structures 210 may be filled with the molding layer 400.

According to some embodiments, the second redistribution substrate 300 may be provided on the molding layer 400. The second redistribution substrate 300 may cover the upper surface of the molding layer 400 and the upper surface of the connection structures 210.

According to some embodiments, second redistribution substrate 300 may comprise a plurality of second insulation layers 310 that are mutually stacked. FIG. 2 illustrates the lamination of three second insulation layers 310, but the present disclosure is not limited thereto. For example, the number of the second insulation layers 310 stacked within the second redistribution substrate 300 may be provided in various ways. The second insulation layers 310 may comprise organic materials, such as, for example, photo-imageable dielectric (PID) materials. The photo-imageable dielectric material may be a polymer. The photo-imageable dielectric material may comprise, for example, at least one of a photosensitivity polyimide, a polybenzooxazole, a phenol-based polymer, and a benzocyclobutene-based polymer. FIG. 2 shows the boundaries between the second insulation layers 310, but the present disclosure is not limited thereto. According to some embodiments, the interface between the adjacent second insulation layers 310 may be indistinguishable.

According to some embodiments, the second redistribution patterns 320 may be provided within the second insulation layers 310. The second redistribution patterns 320 may have a second via portion 320a and a second wiring portion 320b that are integrally connected to each other. The second wiring portion 320b may be a pattern for a horizontal connection within the second redistribution substrate 300. The second via portion 320a may be a portion that vertically connects the second redistribution patterns 320 within the second insulation layers 310. The second wiring portion 320b may be provided on the second via portion 320a. The second wiring portion 320b may be connected to the second via portion 320a without an interface. The width of the second wiring portion 320b may be larger than the width of the second via portion 320a. In other words, each of the second redistribution patterns 320 may have a cross-section of a T shape. The second wiring portion 320b of the second redistribution patterns 320 may be positioned on the upper surface of the second insulation layers 310. The second via portion 320a of the second redistribution patterns 320 may pass through the second insulation layers 310 and be connected to the second wiring portion 320b of another second redistribution pattern 320 positioned underneath. Among the second redistribution patterns 320, the uppermost second redistribution pattern 320 may be exposed on the upper surface of the second redistribution substrate 300. The uppermost second redistribution pattern 320 may correspond to a pad for mounting an additional semiconductor chip or a semiconductor package on the second redistribution substrate 300. The second redistribution patterns 320 may comprise a conductive material. For example, the second redistribution patterns 320 may comprise copper (Cu).

Although not illustrated, seed patterns may be placed on the undersides of the second redistribution patterns 320. For example, the seed patterns may cover the lower surface of the second via portion 320a of the corresponding second redistribution patterns 320, a side wall 320c, and the lower surface of the second wiring portion 320b, respectively. The seed patterns may comprise different material than the second redistribution patterns 320. For example, the seed patterns may comprise copper (Cu), titanium (Ti) or alloys thereof. The second redistribution patterns 320 may further comprise a barrier layer (not shown) that prevents diffusion of the material included in the second redistribution patterns 320. The barrier layer may comprise titanium nitride (TiN)

### Or Tantalum Nitride (tan).

According to some embodiments, the second redistribution patterns 320 may be connected to the connection structures 210. Among the second redistribution patterns 320, the lowermost second redistribution pattern 320 may be in contact with the upper surface of the connection structures 210. The second redistribution patterns 320 may be electrically connected to the semiconductor chip 200 via the connection structures 210 and the first redistribution patterns 120.

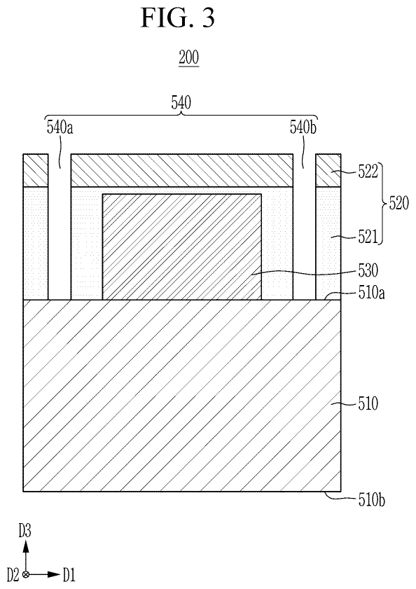

FIG. 3 to FIG. 8 illustrate cross-sectional views of a semiconductor chip 200 according to some embodiments.

Referring to FIG. 3 to FIG. 8, a semiconductor chip 200 According to some embodiments may comprise a semiconductor substrate 510, a semiconductor device layer 530 formed on the semiconductor substrate 510, and an insulation layer 520 surrounding the side surface and the upper surface of the semiconductor device layer 530.

According to some embodiments, a first surface 510a of the semiconductor substrate 510 may be formed of a plane parallel to a first direction D1 and a second direction D2 perpendicular to the first direction D1. The semiconductor substrate 510 may have a first surface 510a and a second surface 510b disposed on a side opposite to the first surface 510a. In other words, the first surface 510a and the second surface 510b of the semiconductor substrate 510 may face each other in the third direction D3. The first surface 510a may correspond to the surface of the semiconductor substrate 510 that is positioned closer, or proximally, to the semiconductor device layer 530, as described below, and the second surface 510b is positioned further away from, or distally to, the semiconductor device layer 530. For example, the first surface 510a of the semiconductor substrate 510 may correspond to the upper surface, and the second surface 510b may correspond to the lower surface in the third direction D3.

According to some embodiments, the semiconductor substrate 510 may comprise silicon (Si), for example, monocrystalline silicon, polycrystalline silicon, or amorphous silicon. According to some embodiments, the semiconductor substrate 510 may comprise a semiconductor element such as germanium (Ge), or a compound semiconductor such as silicon carbide (SiC), gallium arsenide (GaAs), indium arsenide (InAs), and indium phosphide (InP). According to some embodiments, the semiconductor substrate 510 may have a silicon on insulator (SOI) structure.

According to some embodiments, the semiconductor substrate 510 may comprise a buried oxide (BOx) layer. The semiconductor substrate 510 may comprise a conductive region, for example, an impurity-doped well or an impurity-doped structure. According to some embodiments, the semiconductor substrate 510 may comprise various device isolation structures, such as a shallow trench isolation (STI) structure (not illustrated).

According to some embodiments, the semiconductor device layer 530 may comprise a plurality of semiconductor devices. Semiconductor devices may comprise, for example, switches such as transistors, diodes, resistors, and capacitors.

According to some embodiments, an insulation layer 520 surrounding the side surface and the upper surface of the semiconductor device layer 530 may be disposed on the semiconductor substrate 510. The insulation layer 520 may surround the semiconductor device layer 530 on the first surface 510a of the semiconductor substrate 510.

According to some embodiments, the insulation layer 520 may comprise a first passivation layer 521 in direct contact with the side surface and the upper surface of the semiconductor device layer 530 and a second passivation layer 522 positioned over the first passivation layer 521. For example, the first passivation layer 521 and the second passivation layer 522 may be composed of the same material or may be composed of different materials.

For example, the first passivation layer 521 and the second passivation layer 522 may each be composed of silicon oxide or silicon nitride.

According to some embodiments, the insulation layer 520 may be formed of a single layer without being divided into a first passivation layer 521 and a second passivation layer 522.

Referring to FIG. 3, the semiconductor chip 200 according to some embodiments may comprise penetration holes 540 penetrating the insulation layer 520 in the third direction D3. For example, the penetration holes 540 are formed in the depth direction, i.e., the third direction D3, of the insulation layer 520 from the surface of the second passivation layer 522, thereby exposing at least a portion of the insulation layer 520.

According to some embodiments, the penetration holes 540 may be arranged on the semiconductor substrate 510. According to some embodiments, the penetration holes 540 may be positioned in a region adjacent to a region experiencing a compressive stress or a tensile stress around the semiconductor device layer 530.

According to some embodiments, the penetration holes 540 may comprise a first penetration hole 540a and a second penetration hole 540b positioned around the semiconductor device layer 530. For example, the first penetration hole 540a and the second penetration hole 540b may be positioned on both sides of the semiconductor device layer 530, but this is not limited to this, and the number and position of the penetration holes 540 may be changed variously as needed.

According to some embodiments, the length of the penetration holes 540 along the depth direction, or the third direction D3, may be substantially the same as the length of the insulation layer 520 along the depth direction or the third direction D3. In other words, the length of the penetration holes 540 along the third direction D3 may be substantially the same as the length of the insulation layer 520 along the third direction D3. However, it is not limited to this, and the length of the penetration holes 540 according to the third direction D3 can be varied. For example, the length of the penetration holes 540 along the third direction D3 may be smaller than the length of the insulation layer 520 along the third direction D3.

According to various embodiments, the flat area shape of the penetration holes 540 may be formed of a circle, a quadrangle, a polygon, etc. For example, if the flat area shape of the penetration holes 540 is circular, the width of the penetration holes 540 may correspond to the diameter. Although not illustrated in FIG. 3, the width (e.g., the diameter) of the penetration holes 540 may be different in the first direction D1 and the second direction D2. For example, the widths (e.g., the diameters in the first direction D1 and the second direction D2) of the first penetration hole 540a and the second penetration hole 540b may be different.

As described above, with respect to FIGS. 1 and 2, the semiconductor chip 200 according to the present disclosure may reduce or eliminate warping of the semiconductor chip 200. Including the penetration holes 540 in the region adjacent to the region subject to the compressive stress or the tensile force may relax or reduce the compressive stress of tensile force on the semiconductor chip 200 during polishing or other processing steps.

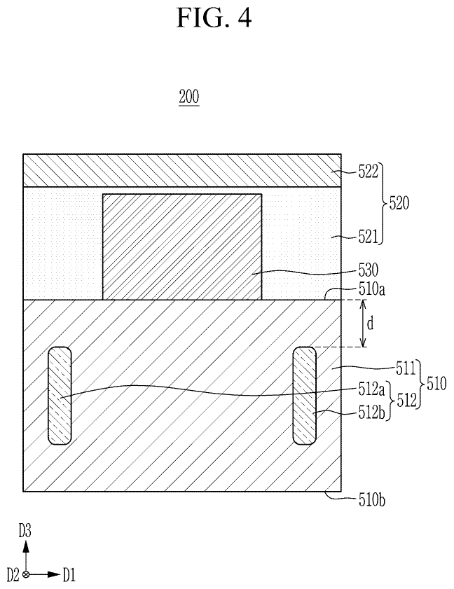

Referring to FIG. 4, the semiconductor substrate 510 of the semiconductor chip 200, according to some embodiments, may comprise a first region 511 having a single crystal structure and a second region 512 having a different crystal structure from the first region 511. In the present disclosure, the second region 512 may be referred to as a modified region.

According to some embodiments, the second region 512 may comprise polycrystalline silicon or amorphous silicon. In other words, the first region 511 may be composed of monocrystalline silicon, and the second region 512 may be composed of polycrystalline silicon or amorphous silicon.

According to some embodiments, the second region 512 may be positioned in a region spaced apart from the first surface 510a of the semiconductor substrate 510 by a first distance d in the third direction D3. However, it is not limited thereto, and the second region 512 may not be spaced apart from the first surface 510a of the semiconductor substrate 510 in the third direction D3. In other words, the second region 512 may be in contact with the first surface 510a of the semiconductor substrate 510.

According to some embodiments, the second region 512 may be positioned adjacent to a region experiencing the compressive stress or the tensile stress within the semiconductor substrate 510. According to various embodiments, the second region 512 may consist of a single region or a plurality of regions. For example, the second region 512 may comprise a twenty-first region 512a and twenty-second region 512b, which is positioned apart from the twenty-first region 512a in the first direction D1. According to some embodiments, the second region 512 may comprise one region or three or more regions.

According to some embodiments, the shape, position and size of the second region 512 may be varied.

According to some embodiments, for example as illustrated in FIG. 4, the second region 512 may be a pillar shape extending along the third direction D3.

According to some embodiments, the second region 512 may comprise a plurality of regions having the same length along the third direction D3. For example, as illustrated in FIG. 4, the twenty-first region 512a and the twenty-second region 512b may have the same length along the third direction D3. As another example, although not shown, the twenty-first region 512a and the twenty-second region 512b may have different lengths along the third direction D3.

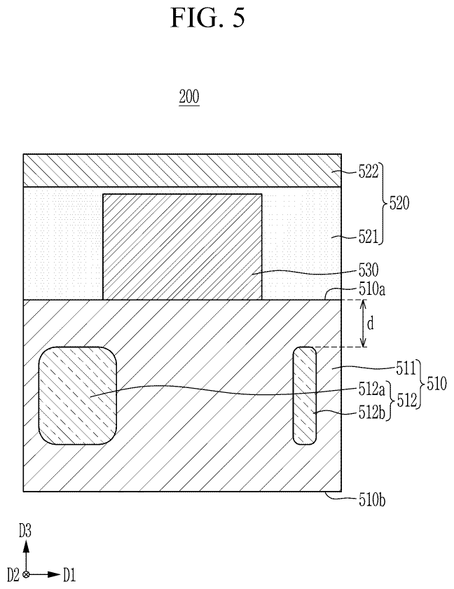

According to some embodiments, the second region 512 may comprise a plurality of regions having the same width along the same first direction D1. For example, as illustrated in FIG. 4, the twenty-first region 512a and the twenty-second region 512b may have the same width along the first direction D1. For example, as illustrated in FIG. 5, the twenty-first region 512a and the twenty-second region 512b may have different widths along the first direction D1.

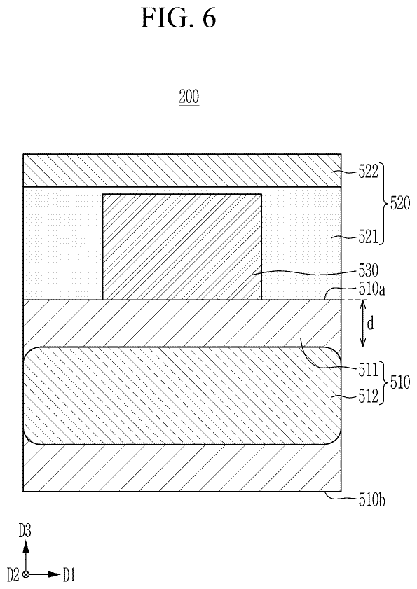

Referring to FIG. 6, the second region 512 may be positioned on the entire region of the semiconductor substrate 510 on the plane. For example, the length of the second region 512 along the first direction D1 may correspond to the length of the semiconductor substrate 510 along the first direction D1. Also, for example, the length of the second region 512 along the second direction D2 may correspond to the length of the semiconductor substrate 510 along the second direction D2. The second region 512 may be positioned away from the first surface 510a of the semiconductor substrate 510 by a first distance d. However, this is not limited thereto, and the second region 512 may not be spaced apart from the first surface 510a of the semiconductor substrate 510 in the third direction D3. In other words, the second region 512 may be in contact with the first surface 510a of the semiconductor substrate 510.

As described above, the semiconductor chip 200 according to the present disclosure may reduce or eliminate any warping of the semiconductor chip 200. The second region 512 including polycrystalline silicon or amorphous silicon in the region adjacent to the region subject to the compressive stress or tensile force may relax or reduce the compressive stress of tensile force on the semiconductor chip 200 during polishing or other processing steps.

In addition, as described above, the semiconductor chip 200 according to the present disclosure may suppress the warpage of the semiconductor chip 200 more effectively by including the second region 512 including polycrystalline silicon or amorphous silicon in the wide region of the semiconductor substrate 510.

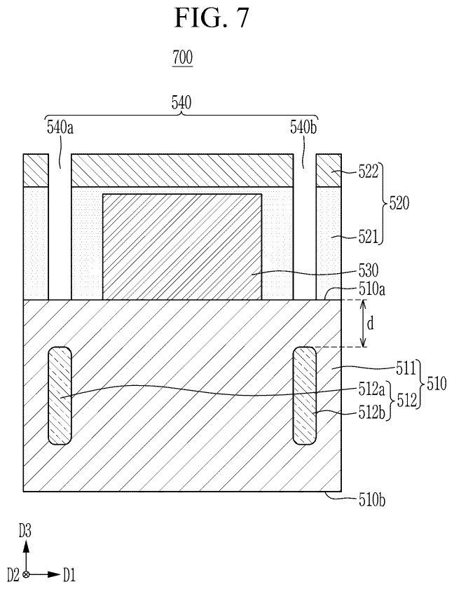

Referring to FIG. 7, the semiconductor chip 200 according to some embodiments may comprise both a penetration holes 540 and a second region 512.

According to some embodiments, the semiconductor chip 200 may comprise a second region 512 including polycrystalline silicon or amorphous silicon in the semiconductor substrate 510 and penetration holes 540 that at least partially overlap the second region 512 in the third direction D3.

For example, the first penetration hole 540a may overlap at least partially the twenty-first region 512a in the third direction D3. Also, for example, second penetration hole 540b may overlap at least partially the twenty-second region 512b in the third direction D3.

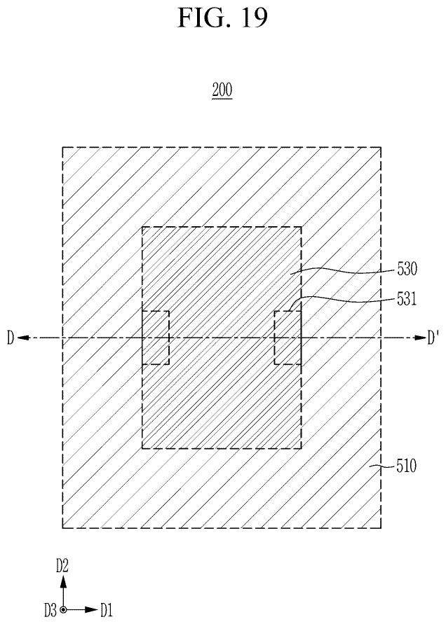

Referring to FIG. 19 to FIG. 26, as described below, by irradiating a laser 600 through the first penetration hole 540a and the second penetration hole 540b respectively to form the twenty-first region 512a and the twenty-second region 512b, any warping or deformation of the semiconductor chip 200 may be suppressed, reduced, or eliminated more effectively compared to conventional methods.

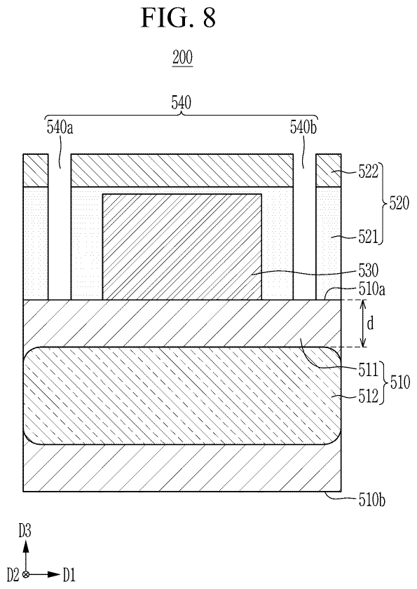

Referring to FIG. 8, the semiconductor chip 200, according to some embodiments, may comprise both a penetration holes 540 and a second region 512.

According to some embodiments, the second region 512 may be positioned on the entire region of the semiconductor substrate 510 on a plane, and the penetration holes 540 may at least partially overlap the second region 512 in the third direction D3. In other words, the second region 512 may be positioned over the entire region of the semiconductor substrate 510 on a plane, and each of the first penetration hole 540a and the second penetration hole 540b may overlap at least partially the second region 512 in the third direction D3.

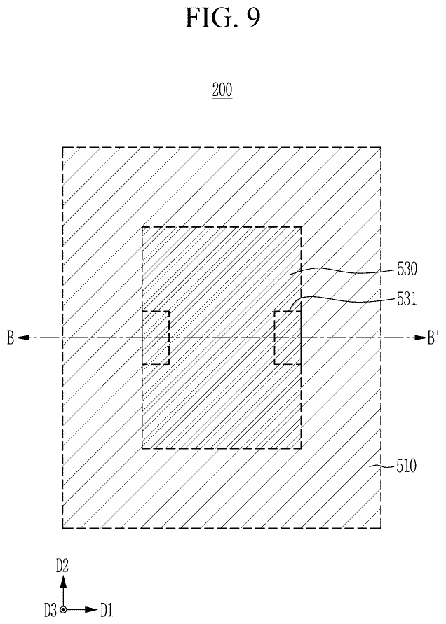

FIG. 9 to FIG. 12 illustrate a manufacturing method of a semiconductor chip according to some embodiments.

In the following, any content that overlaps the above described with reference to FIG. 1 to FIG. 8 may be briefly described or omitted.

In other words, details the semiconductor substrate 510, the insulation layer 520, and the semiconductor device layer 530 described referring to FIG. 1 to FIG. 8 may be simplified or omitted.

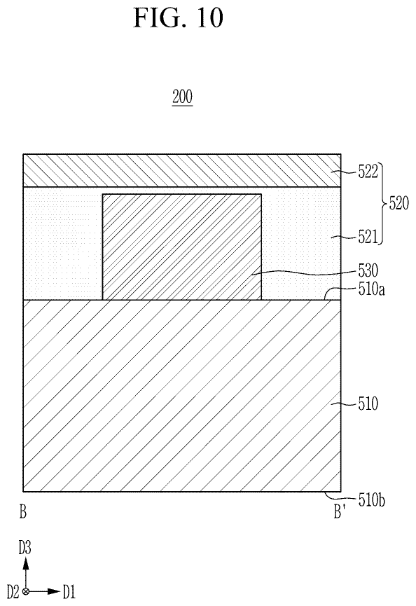

FIG. 9 illustrates a plan view of a semiconductor chip 200 According to some embodiments. FIG. 10 illustrates a cross-sectional view taken along a line B-B′ of FIG. 9.

Referring to FIG. 9 and FIG. 10, the semiconductor chip 200 may comprise at least one target region 531 within the semiconductor device layer 530. Here, the target region 531 may correspond to a region where the compressive stress or tensile force is introduced from the surroundings. In other words, the target region 531 may correspond to a region that needs to relieve the surrounding compressive stress or tensile force to prevent the warpage of the semiconductor chip 200.

Referring to FIG. 10, a semiconductor substrate 510 may be provided having a first surface 510a aligned in the first direction D1 and the second direction D2 and a second surface 510b facing the first surface 510a in the third direction D3.

According to some embodiments, a semiconductor device layer 530 may be formed on the first surface 510a. According to some embodiments, the semiconductor device layer 530 may comprise a plurality of semiconductor devices. Th semiconductor devices may comprise, for example, switches such as transistors, diodes, resistors and capacitors.

According to some embodiments, an insulation layer 520 may be formed surrounding the side surface and upper surface of the semiconductor device layer 530 on the first surface 510a. For example, the insulation layer 520 may be composed of silicon oxide or silicon nitride.

According to some embodiments, the insulation layer 520 may be formed through a deposition process, such as a chemical vapor deposition (CVD) process, or an atomic layer deposition (ALD) process.

According to some embodiments, the insulation layer 520 may comprise a first passivation layer 521 in direct contact with the side surface and the upper surface of the semiconductor device layer 530 and a second passivation layer 522 positioned over the first passivation layer 521. For example, after forming the first passivation layer 521 that is in direct contact with the side surface and upper surface of the semiconductor device layer 530, a second passivation layer 522 may be formed on the first passivation layer 521.

According to some embodiments, the first passivation layer 521 and the second passivation layer 522 may be composed of the same material or may be composed of different materials. According to some embodiments, the insulation layer 520 may be formed as a single layer without being separated into the first passivation layer 521 and the second passivation layer 522.

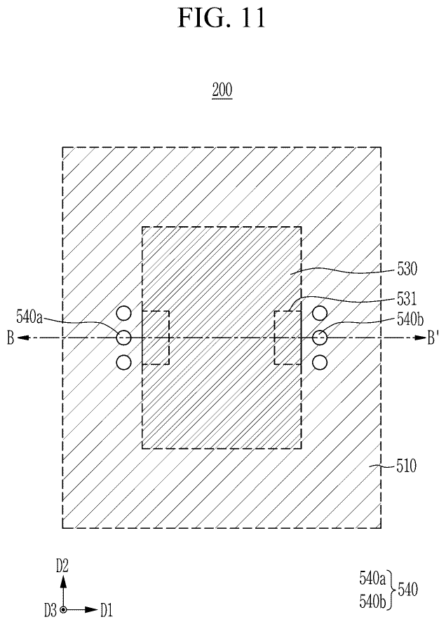

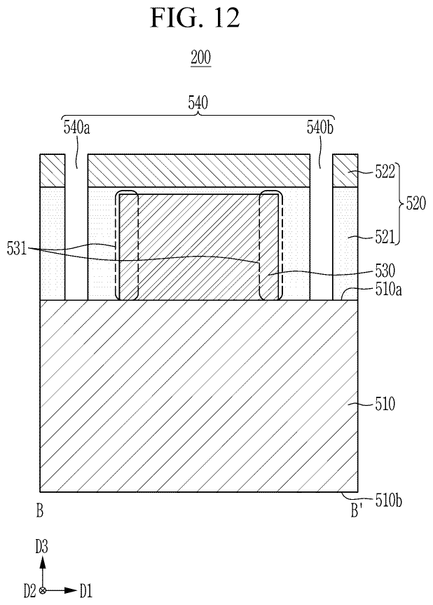

FIG. 11 illustrates a plan view of a semiconductor chip 200 According to some embodiments. FIG. 12 illustrates a cross-sectional view taken along a line B-B′ of FIG. 11.

Referring to FIG. 11 and FIG. 12, according to some embodiments, penetration holes 540 penetrating the insulation layer 520 along a plane (e.g., the third direction D3) perpendicular to the first surface 510a of the semiconductor substrate 510 may be formed around the target region 531. According to some embodiments, the penetration holes 540 may be formed by patterning the insulation layer 520 using an etching process or the like.

According to some embodiments, the penetration holes 540 may be formed between the side surface of the semiconductor device layer 530 and the side surface of the semiconductor substrate 510. However, it is not limited to this, and the formation position of the penetration holes 540 may be varied based on the position of the target region 531.

FIG. 11 illustrates the formation of six penetration holes 540, but the present disclosure is not limited thereto. The number of the penetration holes 540 formed around the semiconductor device layer 530 may vary. It is contemplated that any number of penetration holes 540 may be formed.

According to some embodiments, the penetration holes 540 may comprise a first penetration hole 540a and a second penetration hole 540b. For example, the first penetration hole 540a and the second penetration hole 540b may be formed simultaneously. However, this is not limited to this, and the first penetration hole 540a and the second penetration hole 540b may be formed sequentially in different processes as needed.

As described above, the semiconductor chip 200 according to the present disclosure may reduce or eliminate any warping of the semiconductor chip 200. Forming the penetration holes 540 around the target region 531 may relax or reduce the compressive stress of tensile force on the semiconductor chip 200 during polishing or other processing steps.

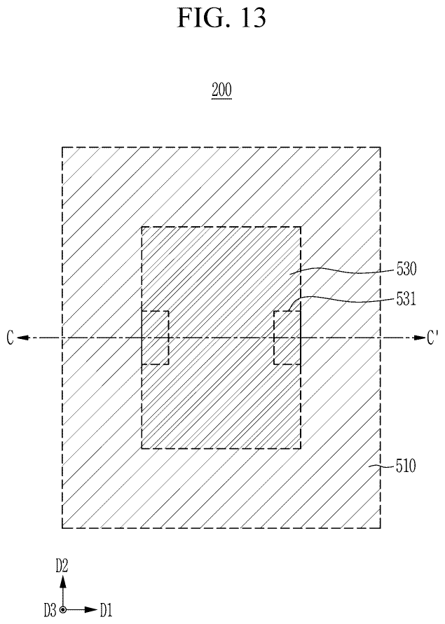

FIG. 13 to FIG. 16 illustrate a manufacturing method of a semiconductor chip, consistent with embodiments of the present disclosure

In the following, any content that overlaps the content described above with reference to FIG. 9 to FIG. 12 may be simplified or omitted. Hereinafter, according to some embodiments, a modified region (e.g., the second region 512) is formed by irradiating a laser 600 on a semiconductor substrate 510.

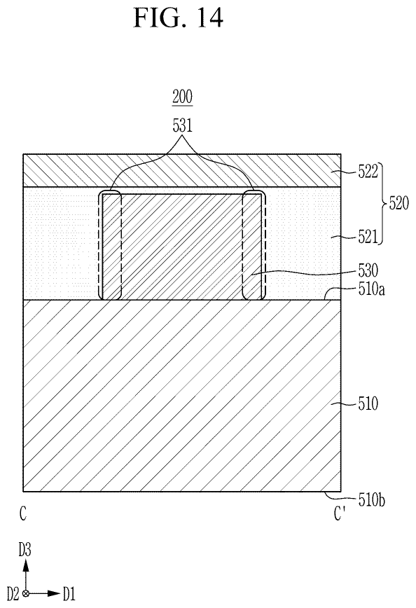

FIG. 13 illustrates a plan view of a semiconductor chip 200 according to some embodiments. FIG. 14 to FIG. 16 correspond to cross-sectional views taken along a line C-C′ of FIG. 13.

Referring to FIG. 13 and FIG. 14, the semiconductor chip 200 may comprise at least one target region 531 within the semiconductor device layer 530. As described above, the target region 531 may correspond to a region into which the compressive stress or the tensile force is introduced from the surroundings.

Referring to FIG. 14, a semiconductor substrate 510 may be provided having a first surface 510a parallel to the first direction D1 and the second direction D2 and a second surface 510b facing the first surface 510a in the third direction D3. According to some embodiments, the semiconductor substrate 510 may have a single crystal structure. For example, the semiconductor substrate 510 may be composed of monocrystalline silicon.

According to some embodiments, a semiconductor device layer 530 may be formed on the first surface 510a of the semiconductor substrate 510. According to some embodiments, the semiconductor device layer 530 may comprise a plurality of semiconductor devices. The semiconductor devices may comprise, for example, switches such as transistors, diodes, resistors and capacitors.

According to some embodiments, an insulation layer 520 may be formed on the first surface 510a of the semiconductor substrate 510 to surround the side surface and the upper surface of the semiconductor device layer 530. According to some embodiments, the insulation layer 520 may be formed through a deposition process, such as a chemical vapor deposition (CVD) process, or an atomic layer deposition (ALD) process.

For example, after forming a first passivation layer 521 that is in direct contact with the side surface and upper surface of the semiconductor device layer 530, a second passivation layer 522 may be formed on the first passivation layer 521.

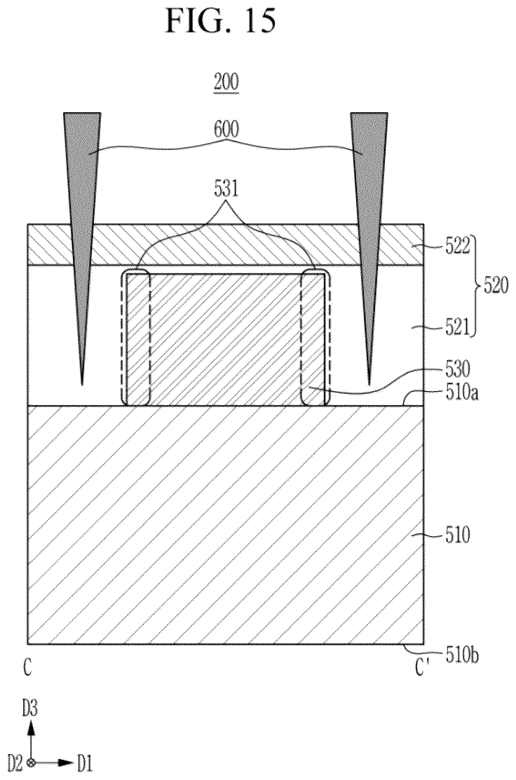

Referring to FIG. 15, a laser 600 may be irradiated to the region adjacent to the target region 531 from a plane perspective. According to some embodiments, the laser 600 may be incident from the surface of the insulation layer 520 and irradiated onto the semiconductor substrate 510.

According to various embodiments, the direction of the laser 600 irradiated on the semiconductor substrate 510 may vary. For example, the direction of the laser 600 irradiated on the semiconductor substrate 510 may be a direction perpendicular to the semiconductor substrate 510, or may be a direction forming a predetermined angle by the first surface 510a of the semiconductor substrate 510. Additionally, according to various embodiments, an energy (or a wavelength) of the laser 600 irradiated to the semiconductor substrate 510 may vary.

According to some embodiments, by irradiating the laser 600 onto the semiconductor substrate 510, the crystal structure of the semiconductor substrate 510 may be changed using a thermal energy. For example, the crystal structure of the semiconductor substrate 510 may be transformed differently depending on a laser energy wavelength, a laser energy density, an irradiation time, a pulse duration, etc.

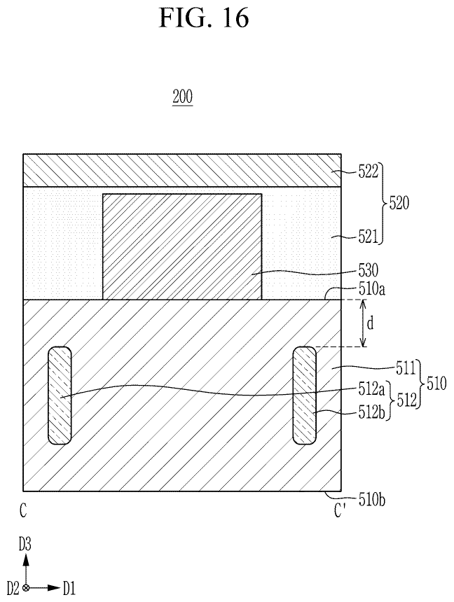

For example, if the tensile force is introduced around the target region 531, a laser 600 having a first energy may be irradiated to the semiconductor substrate 510. The crystal structure of at least some regions of the semiconductor substrate 510 composed of a monocrystalline silicon may be modified by irradiating the laser 600 having the first energy. Accordingly, the second region 512 with the deformed crystal structure may be formed as described with reference to FIG. 16 below.

For example, when irradiating the laser 600 with the first energy, the second region 512 described later may be composed of polycrystalline silicon. As the crystal structure of the regions adjacent the target region 531 is changed into a polycrystalline structure, the tensile force introduced around the target region 531 may be relieved.

Additionally, for example, if the compressive stress is introduced around the target region 531, the semiconductor substrate 510 may be irradiated with a laser 600 having a second energy lower than the first energy. The crystal structure of at least some regions of the semiconductor substrate 510 composed of monocrystalline silicon may be modified by irradiating the laser 600 having the second energy. Accordingly, the second region 512 with the deformed crystal structure may be formed as described with reference to FIG. 16 below.

For example, when irradiating the laser 600 with the second energy, the second region 512 described later may be composed of amorphous silicon. As the crystal structure of the regions adjacent to the target region 531 may be changed into an amorphous structure, the compressive stress introduced around the target region 531 may be relieved.

Referring to FIG. 16, the second region 512 with the deformed crystal structure may be formed by irradiating the laser 600 on the semiconductor substrate 510.

According to some embodiments, the formation position of the second region 512 along the third direction D3 may be determined based on the irradiation depth of the laser 600. In other words, the formation position of the second region 512 along the third direction D3 may be determined based on the depth that the thermal energy of the laser 600 reaches.

For example, as the irradiation depth of the laser 600 is deeper, the first distance d between the second region 512 and the first surface 510a of the semiconductor substrate 510 may be large. In other words, the deeper the laser irradiation depth, the second region 512 may be formed at the deeper position from the first surface 510a.

According to some embodiments, the second region 512 may be formed in a columnar shape extending along the third direction D3. For example, the second region 512 may comprise a twenty-first region 512a and a twenty-second region 522a, which are positioned spaced apart from each other in the first direction D1. The twenty-first region 512a and the twenty-second region 522a may be formed together or sequentially.

According to some embodiments, the constituent material of the second region 512 may be determined based on the energy of the irradiating laser 600. As described above, for example, when irradiating the laser 600 having the first energy, the second region 512 may be formed of the polycrystalline silicon structure. Or, for example, when irradiating the laser 600 having the second energy smaller than the first energy, the second region 512 may be formed of the amorphous silicon structure.

As described above, by irradiating the laser 600 with the different energies depending on the force introduced around the target region 531, the warpage of the semiconductor chip 200 may be effectively suppressed as needed.

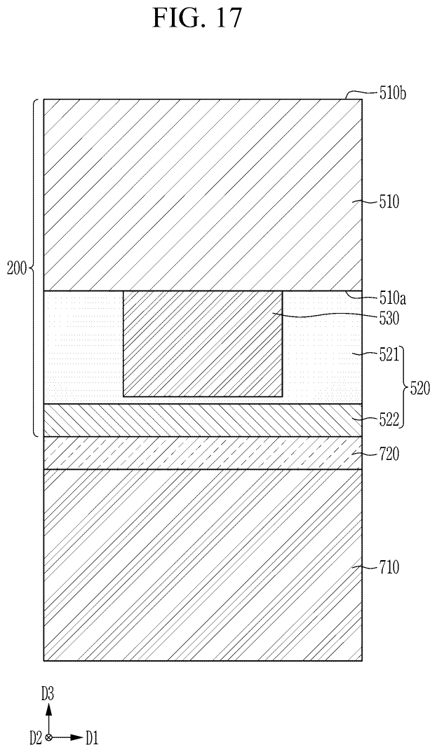

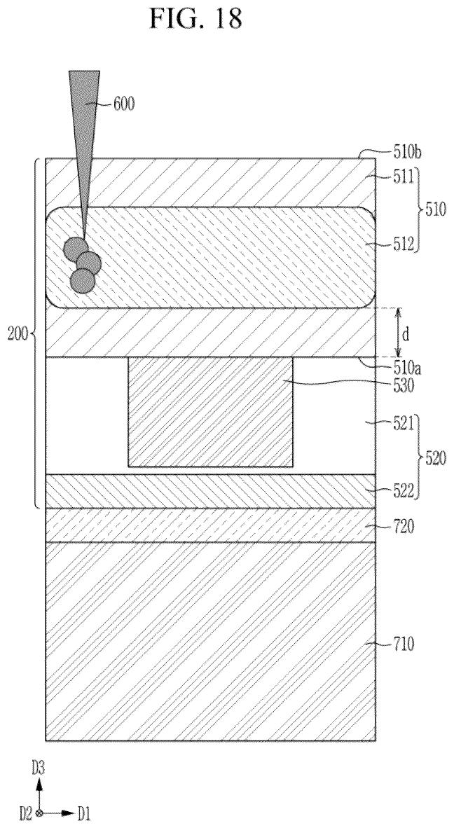

FIG. 17 and FIG. 18 illustrate a manufacturing method of a semiconductor chip, consistent with some embodiment.

Referring to FIG. 17, a support substrate 710 facing the first surface 510a of the semiconductor substrate 510 in the third direction D3 may be formed such that the semiconductor device layer 530 and the insulation layer 520 are disposed between the support substrate 710 and the first surface 510a. For example, the semiconductor device layer 530 and the insulation layer 520 may be disposed on a surface of support substrate 710 in the third direction. For example, the semiconductor device layer 530 and the insulation layer 520 may be disposed on an adhesive layer 720 that is disposed on a surface of support substrate 710 in the third direction.

According to some embodiments, the semiconductor chip 200 may be turned over and the support substrate 710 may be attached to the bottom of the insulation layer 520 using an adhesive layer 720. According to some embodiments, the first surface 510a of the semiconductor substrate 510 may be positioned facing the support substrate 710.

For example, the adhesive layer 720 may comprise a material having adhesive characteristics. For example, the adhesive layer 720 may be a tape-shaped material layer, a liquid coating cured material layer, or a combination thereof.

Referring to FIG. 18, a second region 512 within the semiconductor substrate 510 may be formed by irradiating a laser to the entire region of the semiconductor substrate 510 on a plane.

According to some embodiments, the second region 512 within the semiconductor substrate 510 may be formed by irradiating the laser 600 to the entire region of the semiconductor substrate 510 on a plane while the semiconductor chip 200 is turned over. For example, the length of the second region 512 along the first direction D1 may correspond to the length of the semiconductor substrate 510 along the first direction D1. Also, for example, the length of the second region 512 along the second direction D2 may correspond to the length of the semiconductor substrate 510 along the second direction D2.

According to some embodiments, the constituent material of the second region 512 may be determined based on the energy of the irradiating laser 600. As described above, for example, when irradiating the laser 600 having the first energy, the second region 512 may be formed of the polycrystalline silicon structure. Also, for example, when irradiating with the laser 600 having the second energy smaller than the first energy, the second region 512 may be formed of the amorphous silicon structure.

According to some embodiments, after the second region 512 is formed, the support substrate 710 and the adhesive layer 720 may be removed if necessary.

As described above, warping semiconductor chip 200 may be suppressed, reduced, or eliminated more effectively compared to conventional methods by forming the second region 512 entirely along the first direction D1 within the semiconductor substrate 510.

FIG. 19 to FIG. 26 illustrate a manufacturing method of a semiconductor chip according to another embodiment.

In the following, any content that overlaps the content described above with reference to FIG. 9 to FIG. 18 may be briefly summarized or omitted. In other words, the details about the manufacturing method described with reference to FIG. 9 to FIG. 18 may be brief or omitted.

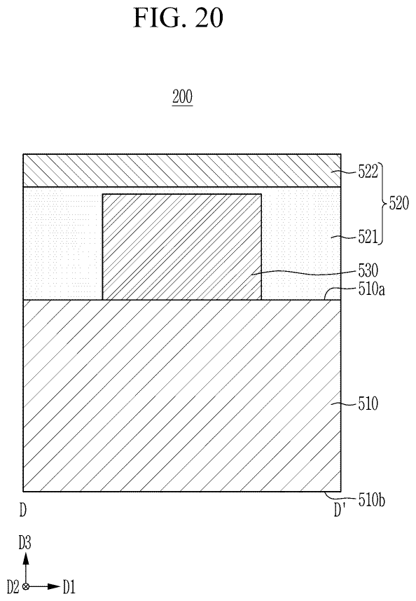

FIG. 19 illustrates the plan view of the semiconductor chip 200 According to some embodiments. FIG. 20 illustrates the cross-sectional view taken along a line D-D′ of FIG. 19.

Referring to FIG. 19 and FIG. 20, a semiconductor substrate 510 having a mono crystal structure may be provided while having a first surface 510a parallel to the first direction D1 and the second direction D2 and a second surface 510b opposite to the first surface 510a.

According to some embodiments, a semiconductor device layer 530 may be formed on the first surface 510a, and an insulation layer 520 may be formed on the first surface 510a to surround the side surface and the upper surface of the semiconductor device layer 530.

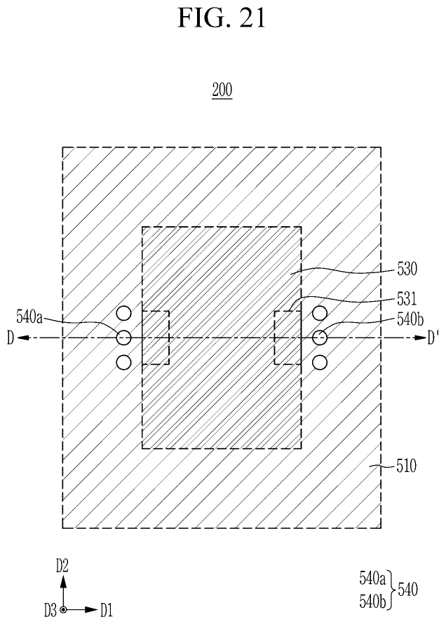

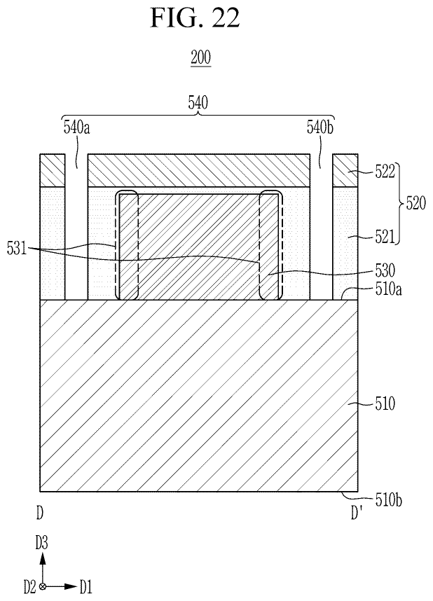

FIG. 21 illustrates a plan view of the semiconductor chip 200 According to some embodiments. FIG. 22 illustrates a cross-sectional view taken along a line D-D′ of FIG. 21.

Referring to FIG. 21 and FIG. 22, according to some embodiments, penetration holes 540 penetrating the insulation layer 520 may be formed in a direction (e.g., the third direction D3) perpendicular to the first surface 510a of the semiconductor substrate 510 around a target region 531 into which the compressive stress or the tensile force is introduced from the surroundings.

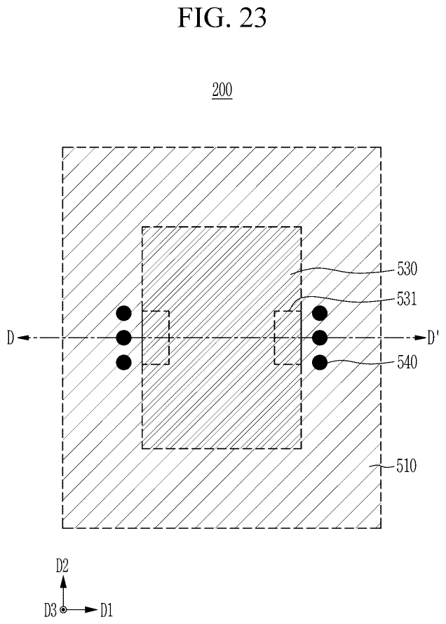

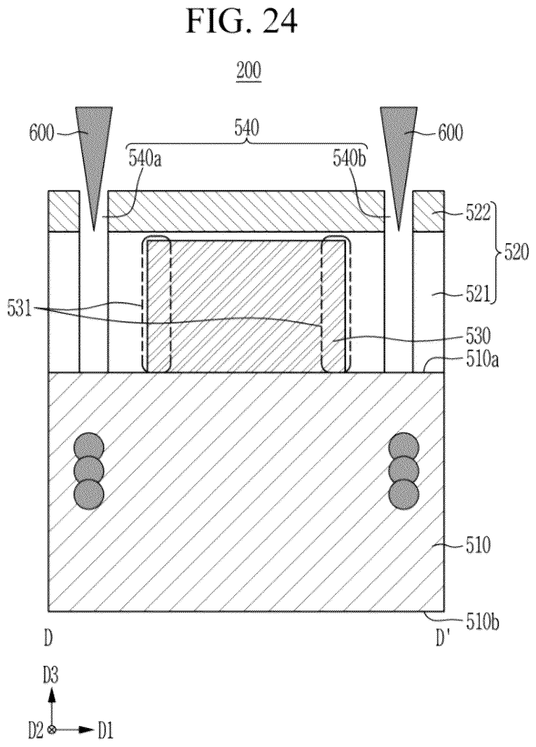

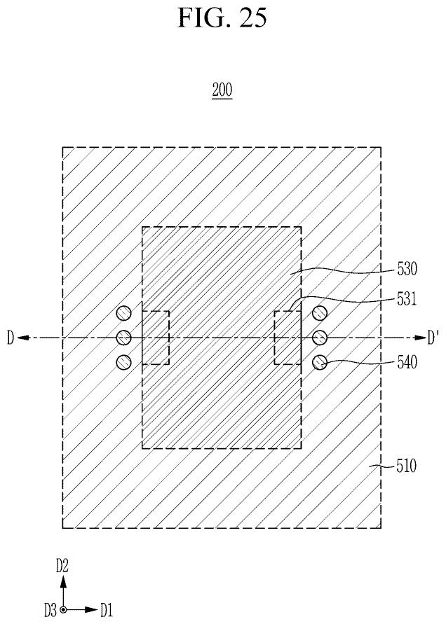

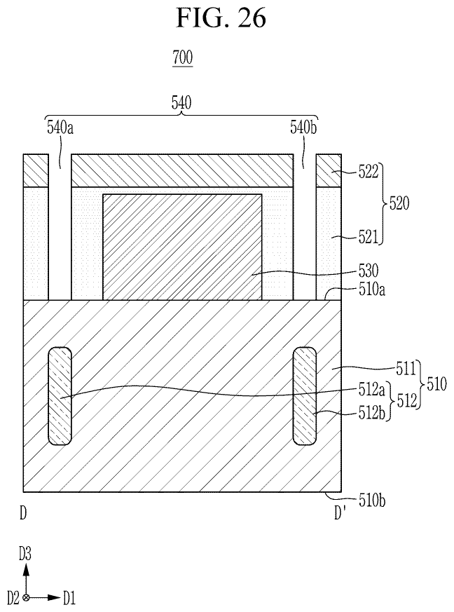

FIG. 23 illustrates a plan view of the semiconductor chip 200 According to some embodiments. FIG. 24 illustrates a cross-sectional view taken along a line D-D′ of FIG. 23. FIG. 25 illustrates a plan view of the semiconductor chip 200 According to some embodiments. FIG. 26 illustrates a cross-sectional view taken along a line D-D′ of FIG. 25.

Referring to FIG. 23 to FIG. 26, according to some embodiments, the laser 600 is irradiated to the semiconductor substrate 510 through the penetration holes 540.

According to some embodiments, by irradiating the laser 600 onto a portion of the semiconductor substrate 510 where the penetration holes 540 are formed, the crystal structure of the semiconductor substrate 510 may be changed using a thermal energy.

For example, a twenty-first region 512a may be formed by irradiating the laser 600 to the portion where the first penetration hole 540a is formed, and a twenty-second region 512b may be formed by irradiating the laser to the portion where the second penetration hole 540b is formed.

As described above, the crystal structure of the second region 512 may be determined based on the energy of the irradiating laser. For example, by irradiating the laser 600 with the different energy magnitudes depending on the compressive stress or tensile force introduced around the target region 531, the introduced compressive stress or tensile force may be alleviated.

As described above, when the laser 600 is irradiated onto the semiconductor substrate 510 at the portion where the penetration holes 540 are formed, the speed at which the heat energy reaches the semiconductor substrate 510 may be high.

Accordingly, when irradiating the laser 600 through the penetration holes 540, warping of the semiconductor chip 200 may be suppressed, reduced, or eliminated more effectively compared to conventional methods.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor chip comprising:
a semiconductor substrate extending from a first surface to a second surface;
wherein the first surface extends along a first axis and a second axis orthogonal to the first axis;
wherein the second surface extends along the first axis and the second axis; and
wherein the first surface faces the second surface and is spaced apart from the second surface along a third axis orthogonal to the first axis and the second axis;
wherein a first region of semiconductor substrate comprises a first single crystal structure, and a second region of the semiconductor substrate comprises a second crystal structure different from the first single crystal structure;
a semiconductor device layer and an insulation layer disposed on the first surface of a semiconductor substrate;
wherein the semiconductor device layer further comprises an upper surface that extends along the first axis and the second axis and a side surface that extends from an edge of the upper surface to the first surface of the semiconductor substrate along the third axis; and
wherein the side surface and the upper surface are covered by the insulation layer.

2. The semiconductor chip of claim 1, wherein:
the second region is spaced apart from the first surface of the semiconductor substrate along the third axis.

3. The semiconductor chip of claim 1, wherein:
the second region is positioned adjacent to a region that is subject to a compressive stress or a tensile stress within the semiconductor substrate.

4. The semiconductor chip of claim 1, wherein:
the second region comprises a polycrystalline silicon or an amorphous silicon.

5. The semiconductor chip of claim 1, wherein:
the second region is formed in a columnar shape extending along the third axis.

6. The semiconductor chip of claim 5, further comprising:
a plurality of penetration holes extending through the insulation layer along the third axis, wherein a penetration hole of the plurality of penetration holes is spaced apart from the second region along the third axis and overlaps with a location of the second region on a common plane.

7. The semiconductor chip of claim 1, wherein:
the second region extends along an entire width along the first axis of the first surface and along an entire width along the second axis of the first surface.

8. The semiconductor chip of claim 1, wherein:
the insulation layer comprises a first passivation layer in direct contact with the side surface and the upper surface of the semiconductor device layer and a second passivation layer disposed on the first passivation layer along the third axis.

9. A semiconductor chip comprising:
a semiconductor substrate extending from a first surface to a second surface;
wherein the first surface extends along a first axis and a second axis orthogonal to the first axis;
wherein the second surface extends along the first axis and the second axis; and
wherein the first surface faces the second surface and is spaced apart from the second surface along a third axis orthogonal to the first axis and the second axis;
a semiconductor device layer extending from a first upper surface to a first lower surface that is disposed on the first surface of the semiconductor substrate;
wherein the first upper surface and the first lower surface both extend along the first axis and the second axis, wherein the first upper surface faces the first lower surface and is spaced apart from the first lower surface along the third axis;
wherein the semiconductor device layer further comprises a side surface that extends from an edge of the first upper surface to an edge of first lower surface along the third axis;
an insulation layer extending from a second upper surface to a second lower surface that is disposed on the first surface of the semiconductor substrate;
wherein, the second upper surface and the second lower surface both extend along the first axis and the second axis, wherein the second upper surface faces the second lower surface and is spaced apart from the second lower surface along the third axis;
wherein the insulation layer covers the side surface and the first upper surface; and
a plurality of penetration holes extending through the insulation layer from the second upper surface along the third axis.

10. The semiconductor chip of claim 9, wherein:
a length of the plurality of penetration holes along the third axis is equal to a length of the insulation layer along the third axis;
wherein the plurality of penetration holes extend from the second upper surface to the second lower surface.

11. The semiconductor chip of claim 9, wherein:
the plurality of penetration holes are disposed adjacent to a region that experiences a compressive or a tensile stress,
wherein the region extends around the semiconductor device layer along the first axis and the second axis.

12. The semiconductor chip of claim 9, wherein:
the insulation layer comprises a first passivation layer extending from a third upper surface along the third axis, wherein the third upper surface extends along the first axis and the second axis;
wherein the first passivation layer is in direct contact with the side surface and the first upper surface of the semiconductor device layer; and
a second passivation layer disposed on the third upper surface of first passivation layer along the third axis.

13. A method of manufacturing a semiconductor chip comprising:
providing a semiconductor substrate that extends from a first surface to a second surface;
wherein the first surface extends along a first axis and a second axis orthogonal to the first axis;
wherein the second surface extends along the first axis and the second axis; and
wherein the first surface faces the second surface and is spaced apart from the second surface along a third axis orthogonal to the first axis and the second axis;
forming a semiconductor device layer that extends from a first upper surface to a first lower surface disposed on the first surface of the semiconductor substrate;
wherein the first upper surface and the first lower surface both extend along the first axis and the second axis, wherein the first upper surface faces the first lower surface and is spaced apart from the first lower surface along the third axis;
wherein the semiconductor device layer further comprises a side surface that extends from an edge of the first upper surface to an edge of first lower surface along the third axis;
forming an insulation layer that extends from a second upper surface to a second lower surface disposed on the first surface of the semiconductor substrate;
wherein the second upper surface and the second lower surface both extend along the first axis and the second axis, wherein the second upper surface faces the second lower surface and is spaced apart from the second lower surface along the third axis; and
irradiating the semiconductor substrate with a laser,
wherein the irradiating forms, in the semiconductor substrate between the first surface and the second surface, a first region having a first single crystal structure and a second region having a second crystal structure different from the first single crystal structure.

14. The method of manufacturing the semiconductor chip of claim 13, wherein:
a location of the second region along the third axis is determined based on an irradiation depth of the laser.

15. The method of manufacturing the semiconductor chip of claim 13, wherein:
the irradiating forms the second region in a region spaced apart from the first surface of the semiconductor substrate along the third axis.

16. The method of manufacturing the semiconductor chip of claim 13, wherein:
the second region is formed in columnar shape extending along the third axis.

17. The method of manufacturing the semiconductor chip of claim 13, wherein:
a material composition of the second region is determined based on a magnitude of energy of the irradiating.

18. The method of manufacturing the semiconductor chip of claim 17, wherein forming the second region comprises:
irradiating a first laser having a first energy to form a modified region having a polycrystalline silicon; or
irradiating a second laser having a second energy smaller than the first energy to form the modified region having an amorphous silicon.

19. The method of manufacturing the semiconductor chip of claim 13, wherein forming the second region comprises:
forming a support substrate on the second upper surface of the insulation layer;
wherein the semiconductor device layer and the insulation layer are disposed between the first surface and the support substrate; and
irradiating an entire width along the first axis of the semiconductor substrate and along an entire second width along the second axis of the semiconductor substrate.

20. The method of manufacturing the semiconductor chip of claim 13, further comprising:
prior to forming the second region, forming a plurality of penetration holes extending from the second upper surface of the insulation layer along the third axis, and
irradiating the laser through the plurality of penetration hole to form the second region.
